(19) United States
(12) Patent Application Publication
(10) Pub. No.: US 2014/0003954 A1
(43) Pub. Date: Jan. 2, 2014

(54) MODIFIED ROTOR BLADE AND METHOD FOR MODIFYING A WEAR CHARACTERISTIC OF A ROTOR BLADE IN A TURBINE SYSTEM

(71) Applicants: David Vincent Bucci, Simpsonville, SC (US); Stephen Gerard Pope, Roebuck, SC (US); Jason Robert Parolini, Greer, SC (US)

(72) Inventors: David Vincent Bucci, Simpsonville, SC (US); Stephen Gerard Pope, Roebuck, SC (US); Jason Robert Parolini, Greer, SC (US)

(73) Assignee: GENERAL ELECTRIC COMPANY, Schenectady, NY (US)

(21) Appl. No.: 13/534,524

(22) Filed: Jun. 27, 2012

(51) Int. Cl. F01D 5/14; C23C 14/06; C23C 14/14

(52) U.S. Cl. 416/229 A; 427/531; 427/523

(57) ABSTRACT

A method for modifying a wear characteristic of a rotor blade in a turbine system and a modified rotor blade for a turbine system are disclosed. The method includes implanting ions of one of a Group 6 element, a Group 14 element, or a Group 15 element through an exterior surface of a rotor blade. The rotor blade is one of a compressor blade or a turbine bucket.

### FIELD OF THE INVENTION

The present disclosure relates in general to rotor blades for use in turbine systems, and more particularly to methods for modifying wear characteristics of the rotor blades and modified rotor blades.

### BACKGROUND OF THE INVENTION

Turbine systems are widely utilized in fields such as power generation. For example, a conventional gas turbine includes a compressor section, a combustor section, and at least one turbine section. The compressor section is configured to compress air as the air flows through the compressor section. The air is then flowed from the compressor section to the combustor section, where it is mixed with fuel and combusted, generating a hot gas flow. The hot gas flow is provided to the turbine section, which utilizes the hot gas flow by extracting energy from it to power the compressor, an electrical generator, and other various loads.

During operation of a turbine system, the various components of the turbine system endure various forms of wearing. Such wearing can lead to damage and/or failure of the individual components and the turbine system in general. Rotor blades, which rotate during operation of the turbine system, are particularly susceptible to wearing. For example, present rotor components may be expected to operate for approximately 150,000 hours and 5,000 starts. Further, in many cases, specific wear sensitive locations on the components, such as on the rotor blades, may tend to wear faster than other locations. These wear sensitive locations may limit the lives of the associated rotor blades.

Various techniques are known in the art for attempting to modify the wear characteristics of turbine system components, and in particular of rotor blades. For example, powder pack deposition techniques have been utilized to coat exterior surfaces of rotor components. However, such techniques are difficult to perform during in-field service repairs, and cause component distortion issues. A particular concern of many techniques is that the exterior surface of the rotor blade is altered. This can lead to performance issues due to the tight tolerances to which the turbine system components are manufactured. Further, the exterior coatings can be relatively brittle, and can be expensive to replace and/or repair.

Thus, improved rotor blades are desired in the art. In particular, rotor blades having improved wear characteristics while maintaining operational tolerances would be desired. For example, improved methods for modifying wear characteristics of rotor blades, and improved modified rotor blades, would be advantageous.

### BRIEF DESCRIPTION OF THE INVENTION

Aspects and advantages of the invention will be set forth in part in the following description, or may be obvious from the description, or may be learned through practice of the invention.

In one embodiment, a method for modifying a wear characteristic of a rotor blade in a turbine system is disclosed. The method includes implanting ions of one of a Group 6 element, a Group 14 element, or a Group 15 element through an exterior surface of a rotor blade. The rotor blade is one of a compressor blade or a turbine bucket.

In another embodiment, a modified rotor blade for a turbine system is disclosed. The modified rotor blade includes a rotor blade. The rotor blade includes a body and an exterior surface. The body includes a base layer and an implantation layer. The implantation layer is disposed between the base layer and the exterior surface. The implantation layer includes a base metal and a plurality of ions implanted into the base metal through the exterior surface. The ions are of one of a Group 6 element, a Group 14 element, or a Group 15 element. The rotor blade is one of a compressor blade or a turbine bucket.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 is a partial cross-sectional view of a gas turbine according to one embodiment of the present disclosure;

FIG. 2 is a perspective view of a compressor blade according to one embodiment of the present disclosure;

FIG. 3 is a perspective view of a turbine bucket according to one embodiment of the present disclosure;

FIG. 4 is a cross-sectional view of a modified rotor blade according to one embodiment of the present disclosure; and

FIG. 5 is a schematic diagram of an ion deposition apparatus according to one embodiment of the present disclosure.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

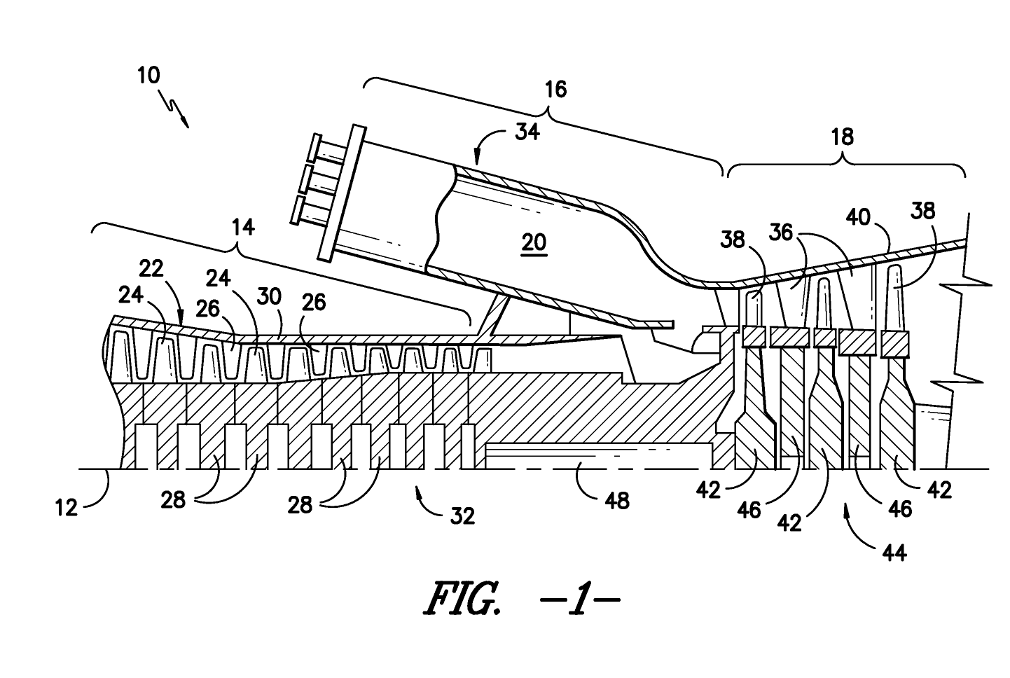

Referring now to the drawings, FIG. 1 illustrates a partial, cross-sectional view of one embodiment of a turbine system 10. In this embodiment, the turbine system is a gas turbine. It should be understood that the turbine system 10 of the present disclosure need not be a gas turbine system, but rather may be any suitable turbine system 10, such as a steam turbine system or other suitable system. The turbine system 10 as shown is cut-off at the turbine's centerline 12. As shown, the turbine system 10 includes a compressor section 14, a combustion section 16 disposed downstream of the compressor section 14 and a turbine section 18 disposed downstream of the combustion section 16. The compressor section 14 may generally be configured to pressurize air flowing into the turbine system 10. A portion of the pressurized air or working fluid then flows into the combustion section 16, wherein the air is mixed with fuel and combusted. Hot gases of combustion then flow through a transition piece 20 along an annular hot gas path to the turbine section 18 to drive the gas turbine 10 and generate power.

In several embodiments, the compressor section 14 may include an axial flow compressor 22 having a plurality of compressor stages characterized by alternating rows of compressor blades 24 and stator vanes 26. Specifically, each compressor stage may include a row of circumferentially spaced compressor blades 24 mounted to a compressor rotor wheel 28 and a row of circumferentially spaced stator vanes 26 attached to a static compressor casing 30. The alternating rows of compressor blades 24 and stator vanes 26 may generally be configured to incrementally increase the pressure of the air flowing through the compressor 22 such that a desired increase in pressure is reached. The compressor rotor wheels 28, along with the compressor blades 24, generally comprise the rotating components of the compressor 22 and, thus, may form a compressor rotor assembly 32. For example, in several embodiments, the compressor rotor disks 28 may be stacked axially against one another about the turbine centerline 12 such that torque may be transmitted between the rotor disks 28.

The combustion section 16 of the gas turbine 10 may generally be characterized by a plurality of combustors 34 (one of which is shown) disposed in an annular array about the turbine centerline 12. Each combustor 34 may generally be configured to receive a portion of the pressurized air discharged from the compressor 22, mix the air with fuel to form an air/fuel mixture and combust the mixture to produce hot gases of combustion. As indicated above, the hot gases of combustion may then flow from each combustor 34 through a transition piece 20 to the turbine section 18 of the gas turbine 10.

The turbine section 18 may generally include a plurality of turbine stages characterized by alternating rows of turbine nozzles 36 and turbine buckets 38. In particular, each turbine stage may include a row of circumferentially spaced turbine nozzles 36 attached to a static turbine casing 40 and a row of circumferentially spaced turbine buckets 38 mounted to a turbine rotor wheel 42. The alternating rows of turbine nozzles 36 and buckets 38 may generally be configured to incrementally convert the energy of the hot gases of combustion into work manifested by rotation of the turbine rotor disks 42. The turbine rotor wheels 42, along with the turbine buckets 38, may generally comprise the rotating components of the turbine section 18 and, thus, may form a turbine rotor assembly 44. Similar to the compressor rotor wheels 28, the turbine rotor wheels 42 may generally be stacked together axially along the turbine centerline 12. For example, as shown in FIG. 1, the turbine rotor wheels 42 may be spaced apart from one another by spacer wheels 46, with the rotor wheels 42 and spacer wheels 46 being stacked axially against one another such that torque may be transmitted between the rotor disks 42. Spacer wheels may additionally or alternatively space art the compressor rotor wheels 28.

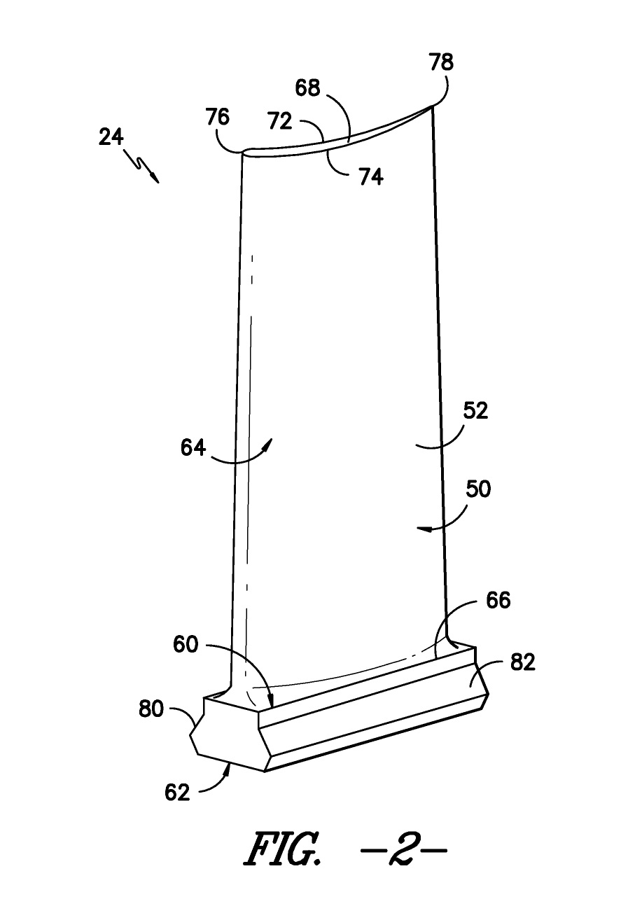

FIG. 2 illustrates a compressor blade 24 according to one embodiment of the present disclosure. The compressor blade 24 as shown includes a body 50 and an exterior surface 52. The body 50 and exterior surface 52 further define various features of the compressor blade 24. For example, the compressor blade 24 may generally include a platform 60, a root 62 extending radially inwardly from the platform 60 and an airfoil 64 extending radially outwardly from the platform 60. The root 62 may generally be configured for attaching the compressor blade 24 to a rotor wheel 28. For example, the root 62 may be configured as a dovetail for connection with a complementary-shaped mating dovetail channel (not shown) of the rotor wheel 28. The airfoil 64 of each compressor blade 24 may generally extend radially between an airfoil base 66 disposed at the platform 60 and an airfoil tip 68 disposed opposite the airfoil base 66. Additionally, the airfoil 64 may generally define an aerodynamic shape. For example, the airfoil 64 may include a pressure side 72 and suction side 74 each extending between a leading edge 76 and a trailing edge 78.

The root 62 may additionally include various portions configured for attaching the compressor blade 24 to a rotor wheel 28. For example, a root 62 may include pressure faces, which may contact corresponding faces of a mating channel defined in the rotor wheel 28. The pressure faces may transmit loads to the corresponding faces of the mating channels due to centrifugal forces exerted on the compressor blade 24 during operation of the turbine system 10. For example, a root 62 may include a pressure side pressure face 80 and a suction side pressure face 82, as shown.

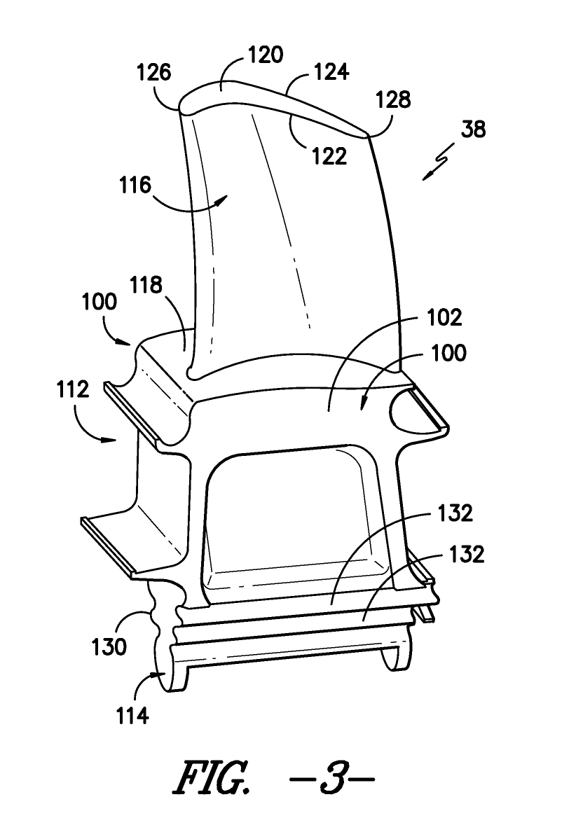

FIG. 3 illustrates a turbine bucket 38 according to one embodiment of the present disclosure. The turbine bucket 38 as shown includes a body 100 and an exterior surface 102. The body 100 and exterior surface 102 further define various features of the turbine bucket 38. For example, the turbine bucket 38 may generally include a platform 110, a shank 112 extending radially inwardly from the platform 110, a root 114 extending radially inwardly from the shank 112, and an 116 extending radially outwardly from the platform 110. The root 114 may generally be configured for attaching the turbine bucket 38 to a rotor wheel 42. For example, the root 114 may be configured as a dovetail for connection with a complementary-shaped mating dovetail channel (not shown) of the rotor wheel 42. The airfoil 116 of each turbine bucket 38 may generally extend radially between an airfoil base 118 disposed at the platform 110 and an airfoil tip 120 disposed opposite the airfoil base 118. Additionally, the airfoil 116 may generally define an aerodynamic shape. For example, the airfoil 116 may include a pressure side 122 and suction side 124 each extending between a leading edge 126 and a trailing edge 128.

The root 114 may additionally include various portions configured for attaching the turbine bucket 38 to a rotor wheel 42. For example, a root 114 may include pressure faces, which may contact corresponding faces of a mating channel defined in the rotor wheel 42. The pressure faces may transmit loads to the corresponding faces of the mating channels due to centrifugal forces exerted on the turbine bucket 38 during operation of the turbine system 10. For example, a root 114 may include pressure side pressure faces 130 and suction side pressure faces 132, as shown.

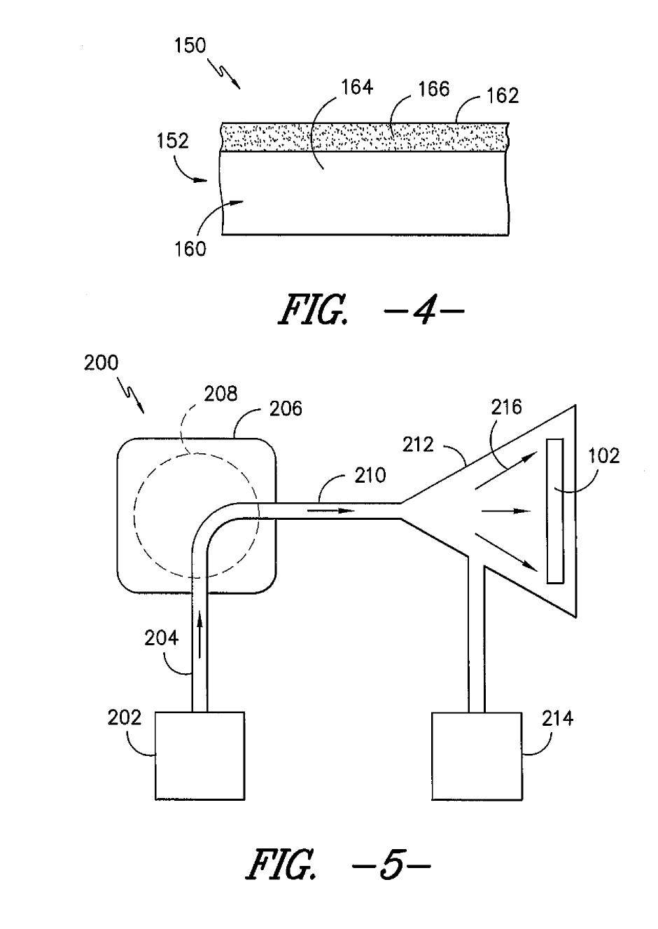

The present disclosure is further directed to modified rotor blades for turbine systems 10. A cross-sectional view of a modified rotor blade 150 is illustrated in FIG. 4. The modified rotor blade 150 includes a rotor blade 152. The rotor blade 152 may be, for example, a compressor blade 24 or a turbine bucket 38. The rotor blade 152 includes a body 160 and an exterior surface 162, as shown and discussed above with regard to compressor blades 24 and turbine buckets 38.

Modified rotor blades 150 according to the present disclosure are modified using ion implantation. During implantation, ions of specific elements may be implanted into the rotor blade 152. The ions are implanted through the exterior surface 162 into the body 160 of the rotor blade 152. As shown in FIG. 4, the body 150 may thus comprise a base layer 164 and an implantation layer 166. The base layer 164 includes the base material that the rotor blade 152 is formed from. In exemplary embodiments, for example, the base material is a base metal. The base metal may be, for example, a suitable aluminum-based, iron-based, nickel-based, austenitic nickel chromium based, or chromium molybdenum vanadium based alloy or superalloy, or any other suitable metal, alloy, or superalloy. In other embodiments, any suitable material may be utilized as a base material. The base layer 164 generally does not include any ions implanted in the base material. The implantation layer 166, on the other hand, includes the base material as well as a plurality of ions implanted into the base material. The implantation layer 166 is disposed between the base layer 164 and the exterior surface 162. Ions are thus implanted through the exterior surface 162 into the implantation layer 166.

The implantation of ions into the body 160 of a rotor blade 152 according to the present disclosure may provide various wear characteristic modifications for the resulting modified rotor blade 150. For example, wear mechanisms that are of increased concern for rotor blade 152 include, for example, fretting wear. Fretting wear is repeated rubbing, which may be cyclical in nature, between two surfaces. Over a period of time, fretting wear will remove material from one or both surfaces in contact. Other wear mechanisms of concern include, for example, corrosion, pitting, and erosion. Ions suitable for implantation into rotor blades 152 according to the present disclosure may modify the various wear characteristics of the rotor blades 152, which are the characteristics of the rotor blade 152 or modified rotor blade 150 in responding to the various wear mechanisms. For example, the implantation of ions may improve the resistance of the modified rotor blade 150 to fretting wear, corrosion, pitting, erosion, or other suitable wear mechanisms that may occur during operation of the turbine system 10.

Ions suitable for implantation into a rotor blade 152 according to the present disclosure include Group 6 elements, Group 14 elements, or Group 15 elements. Group 6 elements include chromium, molybdenum, tungsten, and seaborgium. Group 14 elements include carbon, silicon, germanium, tin, lead, and flerovium. Group 15 elements include nitrogen, phosphorus, arsenic, antimony, bismuth, and ununpentium. In some exemplary embodiments, for example, molybdenum ions and/or chromium ions may be implanted into a rotor blade 152 to form a modified rotor blade 150. The implantation of molybdenum and/or chromium may improve resistance of the modified rotor blade 150 to fretting wear during operation of the turbine system 10, and may provide corrosion and pitting resistance. In other exemplary embodiments, for example, carbon ions and/or nitrogen ions may be implanted into a rotor blade 152 to form a modified rotor blade 150. The implantation of carbon and/or nitrogen may improve resistance of the modified rotor blade 150 to erosion during operation of the turbine system 10.

FIG. 5 illustrates one embodiment of an ion implantation apparatus 200 according to the present disclosure. Ions may be implanted into a rotor blade 152 in a suitable ion implantation apparatus such as the apparatus 200 as shown in FIG. 5 to form a modified rotor blade 150. In general, ion implantation is a process by which ions of a material, such as of an element as discussed above, are accelerated in an electrical field and impacted into a solid material, such as into the exterior surface 162 of a rotor blade 152. The ions may be implanted through the exterior surface 162 into the body 160 of the rotor blade 152, thus forming an implantation layer 166 of a modified rotor blade 150.

Ion implantation apparatus 200 may include, for example, a source chamber 202. Ions of a material are produced in the source chamber 202 by, for example, stripping electrons from a source material in a plasma. The ions are then accelerated in a first acceleration chamber 204, and enter a mass analysis chamber 206. An analyzer magnet 208 may be disposed in the mass analysis chamber 206. Ions suitable for implantation are selected in the mass analysis chamber 206 based on, for example, charge-to-mass ratio, species, isotope, charge state, or another suitable characteristic. The ions are then accelerated in a second acceleration chamber 210. Finally, the ions may enter an implantation chamber 212. The solid material in which the ions are being implanted, such as the rotor blade 152, may be disposed in the chamber. A pump 214 may evacuate the chamber 212 to create a vacuum environment. Beam 216 of ions entering the chamber 212 may be scanned over the rotor blade 152, or portions thereof, to implant ions therein.

In some embodiments, ion implantation may occur over the entire exterior surface 162 of the rotor blade 152 to form the modified rotor blade 150. In other embodiments, however, the implanted ions may be selectively applied to wear sensitive locations on the rotor blade 152. A wear sensitive location is a location that tends to wear faster than surrounding locations, and may thus be a life-limiting location of the rotor component. Examples of life-limiting locations include, for example, a leading edge 76 of a compressor blade 24, a leading edge 126 of a turbine bucket 38, and a pressure face such as a pressure side pressure face 80 or suction side pressure face 82 of a compressor blade 24 or a pressure side pressure face 130 or suction side pressure face 132 of a turbine bucket 38. The implanted ions may thus be selectively applied to one or more wear sensitive locations on a rotor blade 152 to modify wear characteristics at these locations. This selective implantation may in exemplary embodiments occur without any implantation of other locations on the rotor blade 150. Thus, the ions may be selectively disposed in the modified rotor blade 150 only at the wear sensitive locations. Such selective implantation may be facilitated by, for example, shielding portions of the rotor blade 152 other than the wear sensitive locations during the ion implantation process. The shield material may, for example, absorb the ions to prevent them from being implanted into the rotor blade 150 except at the desired wear sensitive locations.

As discussed above, ions are implanted through an exterior surface 162 of a rotor blade 152 to form a modified rotor blade 150. In some embodiments, the ions are implanted to a depth of up to approximately 0.1 microns, such as to a depth of between approximately 0.01 microns and approximately 0.1 microns. The depth may be measured from the exterior surface 162, and may define the thickness of the implantation layer 166 of the body 160. Further, implantation of the ions into the rotor blade 152 to form the modified rotor blade 150 may in some of these embodiments desirably be performed at a temperature in a range between approximately 0° F. and approximately 150° F. Optional heat treating of the modified rotor blade 150 after implantation may further allow the ions to diffuse within the rotor blade 152. It should be understood, however, that such implantation may be performed at any suitable temperature.

In other embodiments, the ions are implanted to a depth of up to approximately 1 micron, such as to a depth of between approximately 0.01 microns and approximately 1 micron. The depth may be measured from the exterior surface 162, and may define the thickness of the implantation layer 166 of the body 160. Further, implantation of the ions into the rotor blade 152 to form the modified rotor blade 150 may in some of these embodiments desirably be performed at a temperature in a range between approximately 500° F. and approximately 1000° F., such as between approximately 800° F. and approximately 1000° F. In these embodiments, the relatively higher temperature levels may allow the ions to diffuse within the rotor blade 152 during implantation. It should be understood, however, that such implantation may be performed at any suitable temperature.

The present disclosure is further directed to methods for modifying a wear characteristic of a rotor blade 152. A method includes, for example, implanting ions through an exterior surface 162 of a rotor blade 152. The ions may, for example, be implanted using ion implantation apparatus 200 as discussed above. The ions are of a Group 6 element, a Group 14 element, or a Group 15 element. The rotor blade 152 may be, for example, a compressor blade 24 or a turbine bucket 38.

The implantation of ions as discussed herein may provide a variety of advantages for rotor blades 152. For example, as discussed, fretting wear may be reduced, which may thus increase the life expectancy of the rotor blades 152. Further, the use of ion implantation as discussed eliminates the need to heat treat or otherwise alter a rotor blade 152, which may cause the dimensions of the rotor blade 152 to be altered out of the appropriate engineering tolerances. Still further, the use of ion implantation eliminates the need to post process the rotor components after implantation. Additionally, the risk of detrimental chemical reactions which could be detrimental to the various properties of the rotor blade 152 are eliminated.

Further, in some embodiments, utilized of ion implantation according to the present disclosure may allow for the creation of a high temperature low cycle fatigue layer on the modified rotor blade 150, such as on a peened surface thereof, without any significant stress relation in the outer layer, such as the peened layer, of the modified rotor blade 150. This would add an additional layer of protection against high temperature low cycle fatigue crack initiation, and the peened layer would provide this protection at increased depths. Further, creation of such a layer would not be possible when using other previously known techniques, such as powder pack techniques with associated high temperature diffusion heat treatments.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method for modifying a wear characteristic of a rotor blade in a turbine system, the method comprising:
implanting ions of one of a Group 6 element, a Group 14 element, or a Group 15 element through an exterior surface of a rotor blade,
wherein the rotor blade is one of a compressor blade or a turbine bucket.

2. The method of claim 1, wherein the implanting step comprises implanting ions of molybdenum.

3. The method of claim 1, wherein the implanting step comprises implanting ions of chromium.

4. The method of claim 1, wherein the implanting step comprises implanting ions of carbon.

5. The method of claim 1, wherein the implanting step comprises implanting ions of nitrogen.

6. The method of claim 1, wherein the implanted ions are selectively applied to a wear sensitive location on the rotor blade.

7. The method of claim 6, wherein the wear sensitive location is a leading edge of the rotor blade.

8. The method of claim 6, wherein the wear sensitive location is a dovetail pressure face.

9. The method of claim 1, wherein the ions are implanted to a depth of up to approximately 0.1 microns.

10. The method of claim 1, wherein the ions are implanted to a depth of up to approximately 1 micron.

11. A modified rotor blade for a gas turbine, the modified rotor blade comprising:
a rotor blade, the rotor blade comprising a body and an exterior surface, the body comprising a base layer and an implantation layer, the implantation layer disposed between the base layer and the exterior surface, the implantation layer comprising a base metal and a plurality of ions implanted into the base metal through the exterior surface,
wherein the ions are of one of a Group 6 element, a Group 14 element, or a Group 15 element, and
wherein the rotor blade is one of a compressor blade or a turbine bucket.

12. The modified rotor blade of claim 11, wherein the ions are molybdenum.

13. The modified rotor blade of claim 11, wherein the ions are chromium.

14. The modified rotor blade of claim 11, wherein the ions are carbon.

15. The modified rotor blade of claim 11, wherein the ions are nitrogen.

16. The modified rotor blade of claim 11, wherein the ions are selectively disposed in a wear sensitive location on the rotor blade.

17. The modified rotor blade of claim 16, wherein the wear sensitive location is a leading edge of the rotor blade.

18. The modified rotor blade of claim 16, wherein the wear sensitive location is a dovetail pressure face.

19. The modified rotor blade of claim 11, wherein the ions are implanted to a depth of up to approximately 0.1 microns.

20. The modified rotor blade of claim 11, wherein the ions are implanted to a depth of up to approximately 1 micron.
